(19) United States
(12) Patent Application Publication
(10) Pub. No.: US 2016/0209714 A1
(43) Pub. Date: Jul. 21, 2016

(54) DISPLAY DEVICE AND MANUFACTURING METHOD THEREOF

(71) Applicant: Samsung Display Co., Ltd., Yongin-si (KR)

(72) Inventors: Huigyeong YUN, Asan-si (KR); Konhaeng LEE, Anyang-si (KR); Kookhyun CHOI, Seoul (KR)

(21) Appl. No.: 14/949,349

(22) Filed: Nov. 23, 2015

(30) Foreign Application Priority Data
Jan. 21, 2015 (KR) 10-2015--0009961

(51) Int. Cl. G02F 1/1343; G02F 1/1335; G02F 1/1362; G02F 1/1333; H01L 27/12; G02F 1/1368

(52) U.S. Cl. CPC G02F 1/134309; H01L 27/124; H01L 27/1259; G02F 1/1368; G02F 1/136286; G02F 1/133345; G02F 1/133512; G02F 1/13624; G02F 2001/133357; G02F 2001/136222; G02F 2001/134345

(57) ABSTRACT

The present invention provides a display device, capable of preventing a short-circuit defect of a common electrode and a pixel electrode, and a method of manufacturing the display device. The display device includes a first substrate having a first radius of curvature; a second substrate being opposed to the first substrate and having a second radius of curvature; a common electrode on the second substrate; a light shielding unit on the common electrode; and a liquid crystal layer between the first substrate and the second substrate.

### CLAIM OF PRIORITY

This application claims the priority to and all the benefits accruing under 35 U.S.C. §119 of Korean Patent Application No. 10-2015-0009961, filed on Jan. 21, 2015, with the Korean Intellectual Property Office (KIPO), the disclosure of which is incorporated herein in its entirety by reference.

### BACKGROUND OF THE INVENTION

1. Field of disclosure

Embodiments of the present invention relate to a display device capable of preventing a short-circuit defect between a common electrode and a pixel electrode and to a method of manufacturing the display device.

2. Description of the Related Art

A liquid crystal display (LCD) device is a type of flat panel displays (FPDs), which is most widely used these days. An LCD device includes two substrates including electrodes formed thereon and a liquid crystal layer interposed therebetween. Upon applying voltage to two electrodes, liquid crystal molecules of the liquid crystal layer are rearranged, thereby adjusting an amount of transmitted light.

In recent years, in response to customers' needs for a stereoscopic screen that may effectively provide a sense of immersion, researches have been continuously conducted to realize a curved-type display device having a predetermined radius of curvature.

A radius of curvature refers to a radius of a circular arc which best approximates an outline curve of an object. An object has a flatter figuration as a radius of curvature increases, while an object has a more round figuration as a radius of curvature decreases.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY OF THE INVENTION

Aspects of embodiments of the present invention are directed to a display device capable of preventing a short-circuit defect between a common electrode and a pixel electrode and to a method of manufacturing the display device.

A liquid crystal display (LCD) device is a type of flat panel displays (FPDs), which is most widely used these days. An LCD device includes two substrates including electrodes formed thereon and a liquid crystal layer interposed therebetween. Upon applying voltage to two electrodes, liquid crystal molecules of the liquid crystal layer are rearranged, thereby adjusting an amount of transmitted light.

In recent years, in response to customers' needs for a stereoscopic screen that may effectively provide a sense of immersion, researches have been continuously conducted to realize a curved-type display device having a predetermined radius of curvature.

A radius of curvature refers to a radius of a circular arc which best approximates an outline curve of an object. An object has a flatter figuration as a radius of curvature increases, while an object has a more round figuration as a radius of curvature decreases.

According to an exemplary embodiment of the present invention, a display device includes a first substrate having a first radius of curvature; a second substrate being opposed to the first substrate and having a second radius of curvature; a common electrode on the second substrate; a light shielding unit on the common electrode; and a liquid crystal layer between the first substrate and the second substrate.

The common electrode may be disposed directly on a surface of the second substrate, the surface of the second substrate being opposed to the first substrate.

The first radius of curvature may be greater than the second radius of curvature.

The display device may further include a planarization layer on the common electrode and on the light shielding unit.

The display device may further include a gate line on the first substrate; a data line intersecting the gate line; a storage line, at least a part of the storage line being disposed parallel to the data line; a thin film transistor (TFT) connected to the gate line and the data line; and a pixel electrode connected to the TFT.

The display device may further include a color filter between the TFT and the pixel electrode.

The display device may further include a capping layer between the color filter and the pixel electrode.

The pixel electrode may include a first sub-pixel electrode and a second sub-pixel electrode being separated from each other; and the TFT may include a first TFT connected to the first sub-pixel electrode, a second TFT connected to the second sub-pixel electrode, and a third TFT connected to the first TFT or to the second TFT.

The first sub-pixel electrode and the second sub-pixel electrode may each include a transverse stem electrode, a longitudinal stem electrode, and a plurality of branch electrodes, the plurality of branch electrodes branching off from the transverse stem electrode and the longitudinal stem electrode and extending therefrom.

The branch electrode may include a first branch electrode branching off from the transverse stem electrode and the longitudinal stem electrode in an upper-left direction and extending therefrom; a second branch electrode branching off from the transverse stem electrode and the longitudinal stem electrode in an upper-right direction and extending therefrom; a third branch electrode branching off from the transverse stem electrode and the longitudinal stem electrode in a lower-left direction and extending therefrom; and a fourth branch electrode branching off from the transverse stem electrode and the longitudinal stem electrode in a lower-right direction and extending therefrom.

The first TFT may include a first gate electrode connected to the gate line, a first source electrode connected to the data line, and a first drain electrode connected to the first sub-pixel electrode. The second TFT may include a second gate electrode connected to the gate line, a second source electrode connected to the data line, and a second drain electrode connected to the second sub-pixel electrode. The third TFT may include a third gate electrode connected to the gate line, a third source electrode connected to the first drain electrode or to the second drain electrode, and a third drain electrode connected to the storage line.

A fraction of a voltage applied to the first drain electrode or to the second drain electrode may be directed to the third source electrode.

A voltage applied to the storage line may be adjusted, thereby controlling a voltage applied from the first drain electrode or from the second drain electrode to the third source electrode.

The storage line may partially overlap the pixel electrode.

According to an exemplary embodiment of the present invention, a method of manufacturing a display device includes forming a first substrate, the first substrate including a gate line and a data line disposed to intersect each other, a TFT connected to the gate line and the data line, and a pixel electrode connected to the TFT; forming a common electrode on a second substrate being opposed to the first substrate; forming a light shielding unit on the common electrode; injecting a liquid crystal layer between the first substrate and the second substrate and adhering the first substrate and the second substrate; and applying pressure to the first substrate and the second substrate to allow the first substrate and the second substrate to have a first radius of curvature and a second radius of curvature, respectively.

The common electrode may be formed directly on a surface of the second substrate, the surface of the second substrate being opposed to the first substrate.

The light shielding unit may be formed on the common electrode to overlap the gate line, the data line, and the TFT.

The first radius of curvature may be greater than the second radius of curvature.

According to embodiments of the present invention, a display device may prevent a short-circuit defect caused between a common electrode and a pixel electrode when pressure is externally imposed thereto.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a block diagram illustrating a display device according to an exemplary embodiment;

FIG. 2 is a schematic oblique view illustrating a display panel of FIG. 1 according to an exemplary embodiment;

FIG. 3 is a circuit diagram illustrating an equivalent circuit of a pixel disposed on a portion A of FIG. 2;

FIG. 4 is a plan view illustrating the pixel disposed on the portion A of FIG. 2;

FIG. 5 is a cross-sectional view taken along line I-I′ of FIG. 4;

FIG. 6 is a plan view illustrating a fundamental structure of a first sub-pixel electrode of FIG. 4; and

FIG. 7 is a flow chart sequentially illustrating a method of manufacturing a display device according to an exemplary embodiment.

### DETAILED DESCRIPTION OF THE INVENTION

Advantages and features of the present invention and methods for achieving them will be made clear from embodiments described below in detail with reference to the accompanying drawings. The present invention may, however, be embodied in many different forms and should not be construed as being limited to the embodiments set forth herein. Rather, these embodiments are provided so that this disclosure will be thorough and complete, and will fully convey the scope of the invention to those skilled in the art. The present invention is merely defined by the scope of the claims. Therefore, well-known constituent elements, operations and techniques are not described in detail in the embodiments in order to prevent the present invention from being obscurely interpreted. Like reference numerals refer to like elements throughout the specification.

The spatially related terms “below”, “beneath”, “lower”, “above”, “upper”, and the like, may be used herein for ease of description to describe the relations between one element or component and another element or component as illustrated in the drawings. It will be understood that the spatially related terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially related terms may be interpreted differently depending on the orientations.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises”, “comprising”, “including”, and “having”, are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

A liquid crystal display (LCD) device is a type of flat panel displays (FPDs), which is most widely used these days. An LCD device includes two substrates including electrodes formed thereon and a liquid crystal layer interposed therebetween. Upon applying voltage to two electrodes, liquid crystal molecules of the liquid crystal layer are rearranged, thereby adjusting an amount of transmitted light.

In recent years, in response to customers' needs for a stereoscopic screen that may effectively provide a sense of immersion, researches have been continuously conducted to realize a curved-type display device having a predetermined radius of curvature.

A radius of curvature refers to a radius of a circular arc which best approximates an outline curve of an object. An object has a flatter figuration as a radius of curvature increases, while an object has a more round figuration as a radius of curvature decreases.

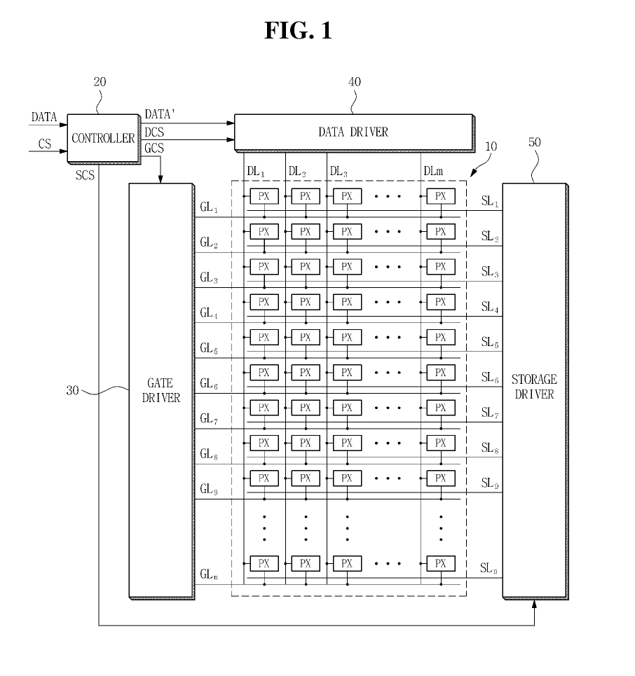

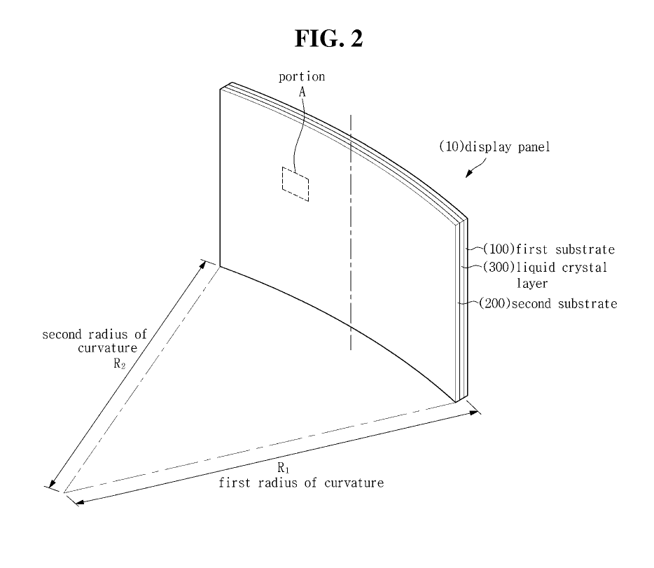

FIG. 1 is a block diagram illustrating a display device according to an exemplary embodiment. FIG. 2 is a schematic oblique view illustrating a display panel of FIG. 1.

The display device according to an exemplary embodiment includes a display panel 10 including a plurality of pixels PX, a controller 20 configured to process an image signal DATA and a control signal CS, which are externally received, to thereby output various signals, a gate driver 30 configured to supply a gate signal to gate lines GL₁ through GLₙ, a data driver 40 configured to supply a data voltage to data lines DL₁ through DLₘ and a storage driver 50 configured to supply a storage voltage to storage lines SL₁ through SLₙ.

The display panel 10 may include the plurality of gate lines GL₁ through GLₙ for transmitting the gate signal in a row direction, the plurality of data lines DL₁ through DLₘ for transmitting the data voltage in a column direction, the plurality of storage lines SL₁ through SLₙ for transmitting the storage voltage in a column direction, and the plurality of pixels PX disposed at intersecting points of the gate line and the data line in a matrix form.

The display panel 10 includes a first substrate 100, a second substrate 200 opposed to the first substrate 100, and a liquid crystal layer 300 interposed between the first substrate 100 and the second substrate 200.

The first substrate 100 may be provided in a curved shape having a first radius of curvature R₁, and the second substrate 200 may be provided in a curved shape having a second radius of curvature R₂. In particular, the first radius of curvature R₁ may be greater than the second radius of curvature R₂. However, the present invention is not limited thereto, and the first substrate 100 and the second substrate 200 may be a flat panel type not imparted with a radius of curvature.

The controller 20 is configured to output, based on the externally received image signal DATA, a corrected image signal DATA′ to the data driver 40. Further, the controller 20 may supply, based on the externally received control signal CS, a gate control signal GCS to the gate driver 30, a data control signal DCS to the data driver 40, and a storage control signal SCS to the storage driver 50. For example, the control signal CS may be a timing signal such as a vertical synchronization signal Vsync, a horizontal synchronization signal Hsync, a clock signal CLK, and a data enable signal DE. Further, the image signal DATA may be a digital signal representing a gray level of light emitted from the pixel PX.

The gate driver 30 is configured to receive the gate control signal GCS from the controller 20 to thereby generate a gate signal, and to supply the gate signal to the pixels PX respectively connected to the plurality of gate lines GL₁ through GLₙ. As the gate signals are sequentially supplied to the pixels PX, the data voltages may be sequentially applied to the pixels PX.

The data driver 40 is configured to receive the data control signal DCS and the corrected image signal DATA′ from the controller 20, and to apply, in response to the data control signal DCS, a data voltage corresponding to the corrected image signal DATA′ to the pixels PX respectively connected to the plurality of data lines DL₁ through DLₘ.

The storage driver 50 is configured to receive the storage control signal SCS from the controller 20 to thereby generate the storage voltage, and to apply the storage voltage to the plurality of storage lines SL₁ through SLₙ.

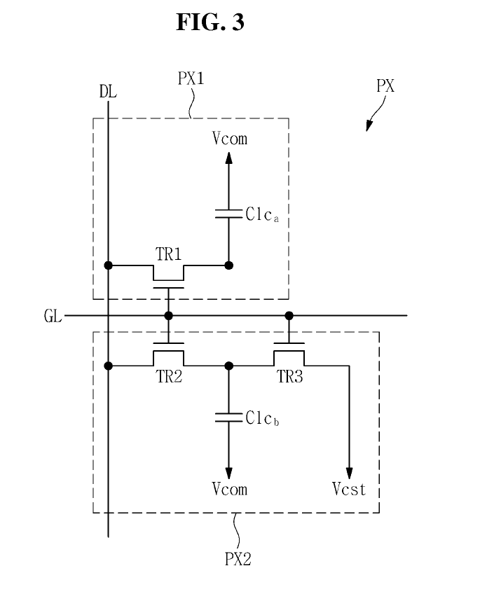

FIG. 3 is a circuit diagram illustrating an equivalent circuit of a pixel disposed on a portion A of FIG. 2.

The pixel PX includes a first sub-pixel PX1 and a second sub-pixel PX2, the second sub-pixel PX2 having a luminance less than that of the first sub-pixel PX1. The first sub-pixel PX1 may include a first thin film transistor (TFT) TR1, and the second sub-pixel PX2 may include a second TFT TR2 and a third TFT TR3.

A control terminal of the first TFT TR1 is connected to the gate line GL; an input terminal of the first TFT TR1 is connected to the data line DL; and an output terminal of the first TFT TR1 is connected to the first sub-pixel electrode of the first sub-pixel PX1. The first sub-pixel electrode of the first sub-pixel PX1 may form a first liquid crystal capacitor Clcₐ along with a common electrode (illustrated as ‘Vcom’).

A control terminal and an input terminal of the second TFT TR2 are respectively connected to the gate line GL and the data line DL, as in the first TFT TR1; and an output terminal of the second TFT TR2 is connected to the second sub-pixel electrode of the second sub-pixel PX2. The second sub-pixel electrode of the second sub-pixel PX2 may form a second liquid crystal capacitor Clc_{b} along with a common electrode (illustrated as ‘Vcom’).

A control terminal of the third TFT TR3 is connected to the gate line GL, as in the first and second TFT TR1 and TR2; an input terminal of the third TFT TR3 is connected to the output terminal of the second TFT TR2; and an output terminal of the third TFT TR3 is connected to a storage line (illustrated as ‘Vcst’).

When the gate signal is applied to the gate line GL, the data voltage, applied to the data line DL, is respectively applied to the first sub-pixel electrode and the second sub-pixel electrode via the first TFT TR1 and the second TFT TR2.

The data voltage transmitted via the first TFT TR1 may be entirely applied to the first sub-pixel electrode, while the data voltage transmitted via the second TFT TR2 may be only partially applied to the second sub-pixel electrode, due to the third TFT TR3. Accordingly, the first sub-pixel PX1 may have a luminance more than that of the second sub-pixel PX2.

For example, when the gate signal is applied to the gate line GL, the data voltage, applied to the input terminal of the second TFT TR2, is applied to the output terminal of the second TFT TR2 via a channel thereof. A fraction of the data voltage transmitted to the output terminal of the second TFT TR2 may be applied to the second sub-pixel electrode, and another fraction of the data voltage may be directed to the storage line Vcst via the third TFT TR3. In this regard, the data voltage applied to the second sub-pixel electrode may be adjusted by varying the voltage applied to the storage line Vcst.

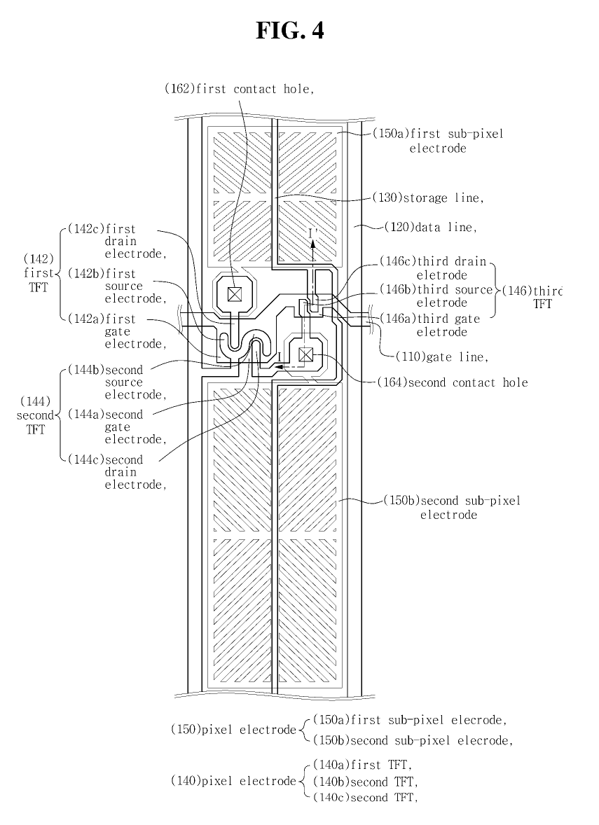

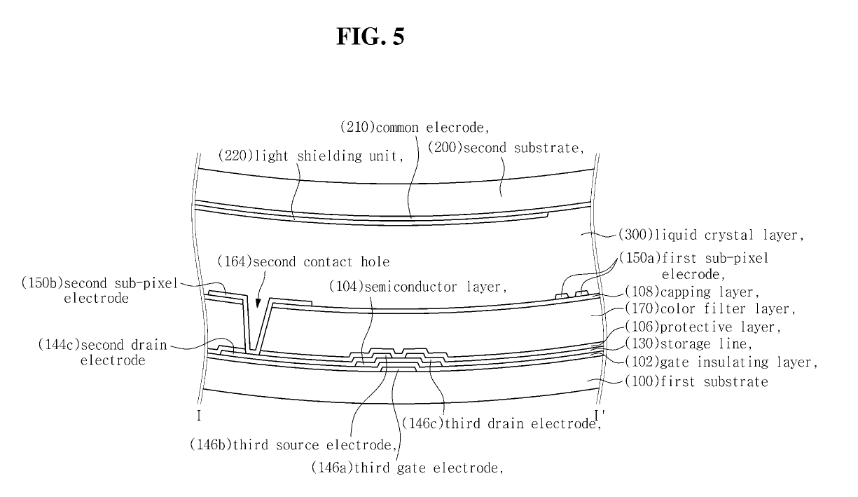

FIG. 4 is a plan view illustrating the pixel disposed on the portion A of FIG. 2, and FIG. 5 is a cross-sectional view taken along line I-I′ of FIG. 4.

The first substrate 100 may include transparent materials, such as glass or plastic.

A gate line 110 may be transversely disposed on the first substrate 100. However, the present invention is not limited thereto, and the gate line 110 may be longitudinally disposed thereon.

The gate line 110 may include, for example, an aluminum (Al)-based metal such as Al or an Al alloy, a silver (Ag)-based metal such as Ag or an Ag alloy, a copper (Cu)-based metal such as Cu or a Cu alloy, a molybdenum (Mo)-based metal such as Mo or a Mo alloy, chromium (Cr), tantalum (Ta), and titanium (Ti). However, the present invention is not limited thereto, and the gate line 110 may have a multi-layer structure including at least two conductive layers that have different physical properties.

A data line 120 may be disposed in a longitudinal direction to intersect the gate line 110, and may be insulated from the gate line 110 by a gate insulating layer 102. However, the present invention is not limited thereto, and in a case where the gate line 110 is disposed in a longitudinal direction, the data line 120 may be disposed in a transverse direction to intersect the gate line 110.

The data line 120 may include refractory metal, such as molybdenum, chromium, tantalum and titanium or metal alloys thereof. However, the present invention is not limited thereto, and the data line 120 may have a multi-layer structure including a refractory metal layer and a low-resistance conductive layer.

A storage line 130 may be disposed at least partially parallel to the data line 120 and may partially overlap a pixel electrode 150.

According to an exemplary embodiment, a part of the storage line 130 may overlap each corresponding longitudinal stem electrode of a first sub-pixel electrode 150a and a second sub-pixel electrode 150b, which are to be described further below, and another part thereof may be bent between the first sub-pixel electrode 150a and the second sub-pixel electrode 150b.

However, the present invention is not limited thereto, and the storage line 130 may be disposed spaced apart from and parallel to the gate line 110 between the first sub-pixel electrode 150a and the second sub-pixel electrode 150b.

The storage line 130 may include, for example, an aluminum (Al)-based metal such as Al or an Al alloy, a silver (Ag)-based metal such as Ag or an Ag alloy, a copper (Cu)-based metal such as Cu or a Cu alloy, a molybdenum (Mo)-based metal such as Mo or a Mo alloy, chromium (Cr), tantalum (Ta), and titanium (Ti). However, the present invention is not limited thereto, and the storage line 130 may have a multi-layer structure including at least two conductive layers that have different physical properties.

A TFT 140 may include a first TFT 142, a second TFT 144, and a third TFT 146.

The first TFT 142 may include a first gate electrode 142a connected to the gate line 110, a first source electrode 142b connected to the data line 120, and a first drain electrode 142c connected to the first sub-pixel electrode 150a through a first contact hole 162.

The second TFT 144 may include a second gate electrode 144a connected to the gate line 110, a second source electrode 144b connected to the data line 120, and a second drain electrode 144c connected to the second sub-pixel electrode 150b through a second contact hole 164.

The third TFT 146 may include a third gate electrode 146a connected to the gate line 110, a third source electrode 146b connected to the second drain electrode 144c, and a third drain electrode 146c connected to the storage line 130.

According to an exemplary embodiment, the first through third gate electrodes 142a, 144a, and 146a may be provided in a shape branching off from the gate line 110 and extending therefrom, but the shape thereof is not limited thereto. For example, the first through third gate electrodes 142a, 144a, and 146a may be integrally formed along with the gate line 110.

The third gate electrode 146a may be insulated from the third source electrode 146b and the third drain electrode 146c by the gate insulating layer 102. A semiconductor layer 104 may be disposed between the gate insulating layer 102 and the third source electrode 146b and between the gate insulating layer 102 and the third drain electrode 146c.

The third gate electrode 146a may include conductive materials, and may have a monolayer or multi-layer structure including one of molybdenum (Mo), aluminum (Al), chromium (Cr), gold (Au), titanium (Ti), nickel (Ni), neodymium (Nd) and copper (Cu), or alloys thereof. However, the present invention is not limited thereto, and the gate electrode 146a may include various conductive materials.

The gate insulating layer 102 may be disposed on the first substrate 100 to cover the third gate electrode 146a, and may prevent infiltration of moisture or undesired materials through the first substrate 100. The gate insulating layer 102 may include insulating materials, and may have a monolayer or multi-layer structure including silicon nitrides (SiNₓ) or silicon oxides (SiOₓ). However, the present invention is not limited thereto, and the gate insulating layer 102 may include various insulating materials.

The semiconductor layer 104 may include an oxide semiconductor. The oxide semiconductor may be a metal oxide semiconductor, and may include one or more of metals, such as zinc (Zn), indium (In), gallium (Ga), tin (Sn), and titanium (Ti), and an oxide thereof. For example, the oxide semiconductor may include at least one of zinc oxide (ZnO), indium-gallium-zinc oxide (IGZO), and indium-zinc-tin oxide (IZTO). However, the present invention is not limited thereto, and the semiconductor layer 104 may include various materials.

The third source electrode 146b may be disposed on the semiconductor layer 104. The third source electrode 146b may include conductive materials, and may have a monolayer or multi-layer structure including one of molybdenum (Mo), aluminum (Al), chromium (Cr), gold (Au), titanium (Ti), nickel (Ni), neodymium (Nd) and copper (Cu), or alloys thereof. However, the present invention is not limited thereto, and the third source electrode 146b may be formed of various conductive materials.

The third drain electrode 146c may be disposed on the semiconductor layer 104 to be spaced apart from the third source electrode 146b. The third drain electrode 146c may include conductive materials, and may have a monolayer or multi-layer structure formed using one of molybdenum (Mo), aluminum (Al), chromium (Cr), gold (Au), titanium (Ti), nickel (Ni), neodymium (Nd) and copper (Cu), or alloys thereof. However, the present invention is not limited thereto, and the third drain electrode 146c may be formed of various conductive materials.

Although not illustrated, an ohmic contact layer may further be disposed between the third source electrode 146b and the semiconductor layer 104 and between the third drain electrode 146c and the semiconductor layer 104. The ohmic contact layer may include a material such as silicide or n+ amorphous silicon doped with n-type impurities at high concentration.

The first and second gate electrodes 142a and 144a, the first and second source electrodes 142b and 144b, and the first and second drain electrodes 142c and 144c may be respectively identical to the third gate electrode 146a, the third source electrode 146b, and the third drain electrode 146c; accordingly, the descriptions pertaining to the first and second gate electrodes 142a and 144a, the first and second source electrode 142b and 144b, and the first and second drain electrodes 142c and 144c will be omitted for brevity.

A protective layer 106 is disposed on the third source electrode 146b and the third drain electrode 146c. The protective layer 106 may include inorganic insulating materials or organic insulating materials, such as silicon nitride (SiNₓ) or silicon oxide (SiOₓ).

The pixel electrode 150 may be formed of transparent conductive materials, and may include the first sub-pixel electrode 150a and the second sub-pixel electrode 150b, which are separated from each other. However, the present invention is not limited thereto, and the pixel electrode 150 may be formed as a single electrode; in such case, the display device according to the present invention may only include the first TFT 142, and the storage line 130 may be absent.

The first sub-pixel electrode 150a and the second sub-pixel electrode 150b may respectively receive data voltages, each having different voltage levels, through the first TFT 142 and the second TFT 144. According to an exemplary embodiment, the data voltage applied to the first sub-pixel electrode 150a may be greater than the voltage applied to the second sub-pixel electrode 150b. However, the present invention is not limited thereto, and when the third TFT 146 is connected to the first TFT 142, the data voltage applied to the second sub-pixel electrode 150b may be greater than the voltage applied to the first sub-pixel electrode 150a.

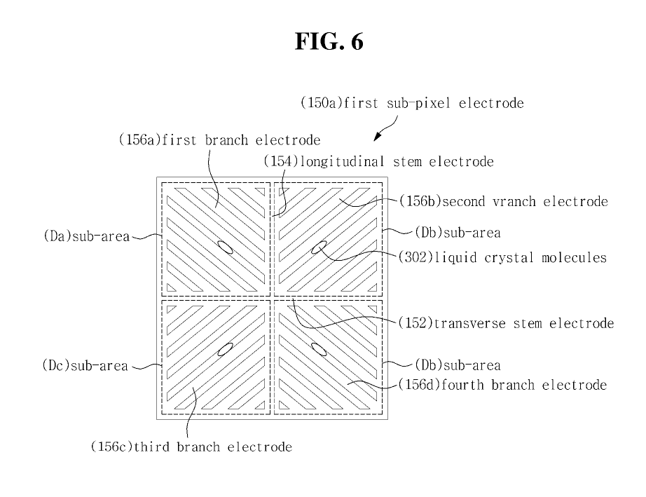

The description pertaining to the first sub-pixel electrode 150a will be described further below with reference to FIG. 6.

A color filter 170 is disposed between the TFT 140 and the pixel electrode 150, and more particularly, between the protective layer 106 and the pixel electrode 150. The color filter 170 may display one of the primary colors, such as the three primary colors of red, green, and blue. However, the color that the color filter 170 may display is not limited thereto, and the color filter 170 may display one of cyan, magenta, yellow, and white. Further, the disposition of the color filter 170 may not be limited thereto, and the color filter 170 may be disposed on the second substrate 200; in such case, an organic layer, formed of organic materials, may be disposed in the position of the color filter 170.

A capping layer 108 is disposed between the pixel electrode 150 and the color filter 170. The capping layer 108 may be disposed to cover the color filter 170. The capping layer 108 is configured to prevent infiltration of undesired materials, produced in the color filter 170, into the liquid crystal layer 300. The capping layer 108 may include inorganic or organic materials such as silicon nitride (SiNₓ), silicon oxide (SiOₓ), or carbon-implanted silicon oxide (SiOC).

The second substrate 200 is opposed to the first substrate 100. The second substrate 200 may include transparent materials, such as glass or plastic.

A common electrode 210 may include transparent conductive materials as in the pixel electrode 150.

The common electrode 210 is disposed on the second substrate 200. In particular, the common electrode 210 may be disposed directly on a surface of the second substrate 200, the surface thereof being opposed to the first substrate 100.

A light shielding unit 220 is disposed on the common electrode 210. The light shielding unit 220 may prevent light leakage occurring at the gate line 110, the data line 120, and the TFT 140, and may include electrically insulating and photosensitive organic materials containing a black pigment.

Although not illustrated, a planarization layer, formed of organic materials and the like, may further be disposed on the light shielding unit 220.

In a conventional display device, a light shielding unit 220 and a planarization layer are sequentially disposed on a surface of a second substrate 200, the surface thereof being opposed to a first substrate 100; and a common electrode 210 is disposed on the planarization layer. That is, the common electrode 210 is disposed on an uppermost layer of the second substrate 200.

In a case where pressure is externally inflicted onto a front surface or onto a rear surface of the conventional display device, or pressure is imposed onto both lateral surfaces thereof in the manufacturing process, the pixel electrode 150 disposed on the uppermost layer of the first substrate 100 and the common electrode 210 disposed on the uppermost layer of the second substrate 200 are brought into contact with each other, thus causing a short-circuit defect.

Further, when the thickness of the color filter 170, disposed on the first substrate 100, increases due to fabrication errors, the pixel electrode 150 disposed on the uppermost layer of the first substrate 100 and the common electrode 210 disposed on the uppermost layer of the second substrate 200 are brought into contact with each other, thus causing a short-circuit defect.

On the other hand, in the display device according to the present invention, the common electrode 210 and the light shielding unit 220 may be sequentially disposed on the second substrate 200. Accordingly, although an external pressure is imposed on the display device, the light shielding unit 220 disposed on the uppermost layer of the second substrate 200 and the pixel electrode 150 disposed on the uppermost layer of the first substrate 100 may be brought into contact with each other, such that a short-circuit defect between the common electrode 210 and the pixel electrode 150 may be prevented.

Further, in the display device according to the present invention, the light shielding unit 220 may be disposed on the common electrode 210, and thus the planarization layer may be omitted where necessary. Accordingly, the display device according to the present invention may obtain a slim thickness.

The liquid crystal layer 300 is disposed between the first substrate 100 and the second substrate 200. The liquid crystal layer 300 may include photopolymerization materials, and the photopolymerization materials may be a reactive monomer or a reactive mesogen.

FIG. 6 is a plan view illustrating a fundamental structure of the first sub-pixel electrode of FIG. 4.

The first pixel electrode 150a may include a transverse stem electrode 152, a longitudinal stem electrode 154, and a plurality of branch electrodes 156a, 156b, 156c, and 156d branching off from the transverse stem electrode 152 and the longitudinal stem electrode 154 and extending therefrom.

The transverse stem electrode 152 and the longitudinal stem electrode 154 may each have a linear shape, and may be combined into a cross shape to form a stem electrode. However, the present invention is not limited thereto, and the transverse stem electrode 152 and the longitudinal stem electrode 154 may each have a greater width from one side of the pixel electrode 150 to a center portion thereof.

The first branch electrode 156a may branch off from the transverse stem electrode 152 and the longitudinal stem electrode 154 and extend in an upper left direction, and the second branch electrode 156b may branch off from the transverse stem electrode 152 and the longitudinal stem electrode 154 and extend in an upper right direction.

Further, the third branch electrode 156c may branch off from the transverse stem electrode 152 and the longitudinal stem electrode 154 and extend in a lower left direction from, and the fourth branch electrode 156d may branch off from the transverse stem electrode 152 and the longitudinal stem electrode 154 and extend in a lower right direction.

Sides of the first through fourth branch electrodes 156a 156b, 156c, and 156d may cause electric-field distortion and produce a horizontal component of the electric field, which may determine an inclination direction of liquid crystal molecules 302. The horizontal component of the electric field may be substantially horizontal with respect to the sides of the first through fourth branch electrodes 156a, 156b, 156c, and 156d. Accordingly, the liquid crystal molecules 302 may be aligned in four different directions in four sub-areas Da, Db, Dc, and Dd of the pixel electrode 150.

Since the second sub-pixel electrode 150b is provided in a same shape as that of the first sub-pixel electrode 150a, the detailed description pertaining thereto will be omitted for brevity. However, the second sub-pixel electrode 150b may have a size different from the size of the first sub-pixel electrode 150b. The scope of the present invention is not limited by the size of the first sub-pixel electrode 150a and the second sub-pixel electrode 150b.

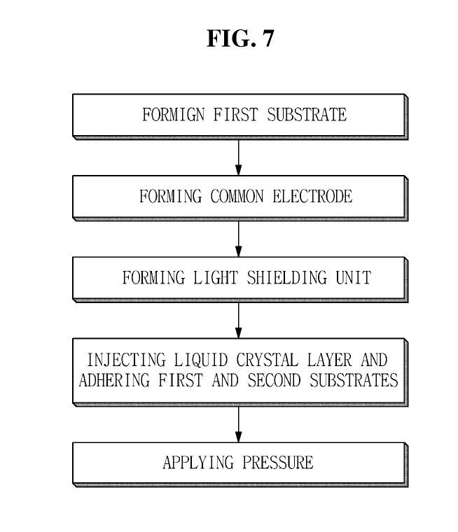

FIG. 7 is a flow chart sequentially illustrating a method of manufacturing a display device according to an exemplary embodiment.

The method of manufacturing the display device according to an exemplary embodiment includes forming a first substrate, the first substrate including a gate line and a data line disposed to intersect each other, a TFT connected to the gate line and the data line, and a pixel electrode connected to the TFT; forming a common electrode on a second substrate opposed to the first substrate; forming a light shielding unit on the common electrode; injecting a liquid crystal layer between the first and second substrates and adhering the first and second substrates; and applying pressure on the first and second substrates to allow the first and second substrates to have a first radius of curvature and a second radius of curvature, respectively.

The descriptions pertaining to the shape of the gate line, the data line, the TFT, and the pixel electrode, formed on the first substrate, are the same as those described with reference to FIGS. 4 and 5, and thus will be omitted for brevity. A color filter may further be formed between the TFT and the pixel electrode.

The common electrode may be formed directly on a surface of the second substrate, the surface thereof being opposed to the first substrate. The common electrode may be formed on the second substrate in a plate form, but the shape of the common electrode is not limited thereto. For example, the common electrode may be provided in a plate form having an aperture.

The light shielding unit is formed on the common electrode to overlap the gate line, the data line, and the TFT. The light shielding unit may be formed on the common electrode in a lattice form.

The size of the first radius of curvature and the size of the second radius of curvature may be adjusted where necessary. In particular, the first radius of curvature may be greater than the second radius of curvature in size.

In the method of manufacturing the display device according to the present invention, it may be desirable that subsequent to the first substrate and the second substrate being adhered together, pressure is applied thereto to thereby manufacture a display device in a curved form. However, the present invention is not limited thereto, and for example, subsequent to pressure being applied to the first substrate and the second substrate, the first substrate and the second substrate may be adhered together to thereby manufacture the display device in a curved form.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings. Various features of the above described and other embodiments can be mixed and matched in any manner, to produce further embodiments consistent with the invention.

What is claimed is:

1. A display device comprising:
a first substrate having a first radius of curvature;
a second substrate being opposed to the first substrate and having a second radius of curvature;
a common electrode on the second substrate;
a light shielding unit on the common electrode; and
a liquid crystal layer between the first substrate and the second substrate.

2. The display device of claim 1, the common electrode being disposed directly on a surface of the second substrate, the surface of the second substrate being opposed to the first substrate.

3. The display device of claim 1, the first radius of curvature being greater than the second radius of curvature.

4. The display device of claim 1, further comprising a planarization layer on the common electrode and on the light shielding unit.

5. The display device of claim 1, further comprising:
a gate line on the first substrate;
a data line intersecting the gate line;
a storage line, at least a part of the storage line being disposed parallel to the data line;
a thin film transistor (TFT) connected to the gate line and the data line; and
a pixel electrode connected to the TFT.

6. The display device of claim 5, further comprising a color filter between the TFT and the pixel electrode.

7. The display device of claim 6, further comprising a capping layer between the color filter and the pixel electrode.

8. The display device of claim 5,
the pixel electrode comprising
a first sub-pixel electrode and
a second sub-pixel electrode being separated from each other, and the TFT comprising
a first TFT connected to the first sub-pixel electrode,
a second TFT connected to the second sub-pixel electrode, and
a third TFT connected to the first TFT or to the second TFT.

9. The display device of claim 8, the first sub-pixel electrode and the second sub-pixel electrode each comprising
a transverse stem electrode,
a longitudinal stem electrode, and
a plurality of branch electrodes,
the plurality of branch electrodes branching off from the transverse stem electrode and the longitudinal stem electrode and extending therefrom.

10. The display device of claim 9, the branch electrode comprising:
a first branch electrode branching off from the transverse stem electrode and the longitudinal stem electrode in an upper-left direction and extending therefrom;
a second branch electrode branching off from the transverse stem electrode and the longitudinal stem electrode in an upper-right direction and extending therefrom;
a third branch electrode branching off from the transverse stem electrode and the longitudinal stem electrode in a lower-left direction and extending therefrom; and
a fourth branch electrode branching off from the transverse stem electrode and the longitudinal stem electrode in a lower-right direction and extending therefrom.

11. The display device of claim 8,
the first TFT comprising
a first gate electrode connected to the gate line,
a first source electrode connected to the data line, and
a first drain electrode connected to the first sub-pixel electrode,
the second TFT comprising
a second gate electrode connected to the gate line,
a second source electrode connected to the data line, and
a second drain electrode connected to the second sub-pixel electrode, and
the third TFT comprising
a third gate electrode connected to the gate line,
a third source electrode connected to the first drain electrode or to the second drain electrode, and
a third drain electrode connected to the storage line.

12. The display device of claim 11, a fraction of a voltage applied to the first drain electrode or to the second drain electrode being directed to the third source electrode.

13. The display device of claim 12, a voltage applied to the storage line is adjusted, thereby controlling a voltage applied from the first drain electrode or from the second drain electrode to the third source electrode.

14. The display device of claim 5, the storage line partially overlapping the pixel electrode.

15. A method of manufacturing a display device comprising:
forming a first substrate, the first substrate including a gate line and a data line disposed to intersect each other, a TFT connected to the gate line and the data line, and a pixel electrode connected to the TFT;
forming a common electrode on a second substrate being opposed to the first substrate;
forming a light shielding unit on the common electrode;
injecting a liquid crystal layer between the first substrate and the second substrate and adhering the first substrate and the second substrate; and
applying pressure to the first substrate and the second substrate to allow the first substrate and the second substrate to have a first radius of curvature and a second radius of curvature, respectively.

16. The display device of claim 15, the common electrode being formed directly on a surface of the second substrate, the surface of the second substrate being opposed to the first substrate.

17. The display device of claim 15, the light shielding unit being formed on the common electrode to overlap the gate line, the data line, and the TFT.

18. The display device of claim, 15, the first radius of curvature being greater than the second radius of curvature.

19. The display device of claim 1, the light shielding unit being electrically insulating.

20. The display device of claim 15, the light shielding unit being electrically insulating.

21. A display device comprising:
a first substrate having a first radius of curvature;
a second substrate being opposed to the first substrate and having a second radius of curvature different from the first substrate;
a common electrode on the second substrate
a pixel electrode on the first substrate;
an electrically insulating light shielding unit between the common electrode and the pixel electrode; and
a liquid crystal layer between the first substrate and the second substrate.
